(19) United States
(12) Patent Application Publication
(10) Pub. No.: US 2009/0008733 A1
(43) Pub. Date: Jan. 8, 2009

(54) Electric field steering cap, steering electrode, and modular configurations for a radiation detector

(76) Inventors: Guilherme Cardoso, Carlsbad, CA (US); Miguel Albert Capote, Carlsbad, CA (US)

Correspondence Address: THE NATH LAW GROUP, 112 South West Street, Alexandria, VA, 22314, US

(21) Appl. No.: 12/073,170

(22) Filed: Feb. 29, 2008

Related U.S. Application Data
(60) Provisional application No. 60/935,676, filed on Aug. 24, 2007.
(60) Provisional application No. 60/904,182, filed on Mar. 1, 2007.

(51) Int. Cl. H01L 31/00; H01L 21/00

(52) U.S. Cl. 257/435; 438/64; 257/E31.001; 257/E21.001

(57) ABSTRACT

A cap for a radiation detection device of the type that utilizes a semiconductor medium includes a bias connection pad, a steering electrode, and a shielding layer. The steering electrode may be a grid steering electrode positioned parallel to the bias connection pad opposite a medium, or may be an electrode disposed perpendicular to the bias connection pad along the edge of a medium. The bias connection pad may be electrically connected or equipotent to the steering electrode. The cap may be formed of flexible circuit board, which may also connect the semiconductor detector to bias, detection or processing circuitry. The bias connection pad and the shielding layer can be maintained with fixed spacing to prevent vibration. A mezzanine card may be used to connect multiple detectors in a modular fashion.

### CROSS REFERENCE TO RELATED APPLICATIONS

This application claims the benefit of U.S. Provisional Patent Application No. 60/935,676 filed Aug. 24, 2007, and of U.S. Provisional Patent Application No. 60/904,182, filed Mar. 1, 2007. The contents of both above applications are hereby incorporated by reference in their entirety.

### BACKGROUND OF THE INVENTION

1. Field of the Invention

The present application relates to radiation detection devices of the type that utilize a semiconductor medium. Specifically, the present application relates to an electric field steering cap for such a detection device.

2. Related Art

A semiconductor detector substrate used for detection of x-rays and gamma rays may comprise cadmium zinc telluride (CdZnTe otherwise known as CZT), cadmium telluride (CdTe), mercuric iodide, (HgI₂) or any other solid state direct conversion detector. Other examples are Si, InSb, GaAs, Ge, TiBr, PbI₂. The amplitude of the electrical pulses derived from such detectors are indicative of the energy of the radiation absorbed by the detector. Although the present disclosure primarily discusses x-ray and gamma-ray detection, the apparatuses and methods herein are applicable to many types of radiation detection. The term “radiation” can include, but is not limited to, gamma rays, alpha radiation, beta radiation, x-rays, ionizing or ionized particles, and neutrons. Such semiconductor detector substrates comprise a plurality of detector cells (e.g., pixel or strip cells) defined by an array of metal contacts on one side of the semiconductor detector substrate. The readout device can comprise a corresponding plurality of readout circuits each corresponding to each of the detector cells in the array. A semiconductor readout substrate is interconnected to the detector substrate with individual pixel cells being connected to their corresponding readout circuits by means of conductors. Concurrently, a bias voltage is applied to a planar or segmented (i.e. with pixel and/or strip arrays) “bias electrode” that is situated on the detector substrate face opposite the pixels in such a manner as to electrically direct charges formed within the detector by interaction with radioactive particles into the pixels. Such a detector-readout assembly or module may then become part of a larger system used for creating images in two or more dimensions from x-rays, alpha, beta, neutrons, gamma rays, or other types of ionizing radioactive particles being emitted by an object to be imaged. Alternately, the detector-readout assembly may be used singly, or in combination with other similar assemblies, to detect the presence of radiation and its energy.

Known x-ray and gamma ray detection and imaging devices suffer from a number of deficiencies. One such deficiency is that charges formed at the edge of the detector substrate can stray onto the walls or edges of the detector where they can be trapped and not contribute to the signals produced by the detector. To ameliorate this problem, electric fields within the detector substrate can be designed so as to steer charges formed near the edges of the substrate away from the edges and toward the nearby pixels cells. In order to form a sufficient electric field so as to steer these charges, steering electrodes are often employed. Such steering electrodes can be applied directly to the detector substrate surface or beneath the detector substrate as a grid, or may surround the detector substrate edges as a band. One problem with prior art approaches that apply the steering electrodes to the detector substrate is that the electrode metallization needs to be applied to the complex surfaces comprising the detector. This is expensive to achieve and difficult to accomplish repeatedly in a production process. Also, if metallization is applied to the detector, it can lead to increased leakage current to the pixel cells, which is harmful to the sensitive signal being detected there. The inclusion of steering electrodes on the surface of the detector substrate involves additional fabrication cost. Furthermore, once applied to the surface of the material it becomes cumbersome to apply different voltages to specific regions of the detectors. It can in some circumstances be desirable to apply a set of voltages to the interpixel regions of the detector to optimally shape the electric filed between electrodes.

Therefore, there is a need to devise an improved method of applying voltages to steering electrodes on radiation detectors in such a way that the charges within the detector can be steered without increasing leakage currents and without expensive and difficult electrode metallization at the detector.

Another problem with the prior art is that the detectors are highly sensitive to noise pickup. Such noise often results from electromagnetic interference. To ameliorate this problem, the detector is often shielded. This is usually accomplished by surrounding the detector with one or more grounded shields. (Note that the detector shown in FIG. 1 is not shielded) While these shields protect the detector from outside electromagnetic noise, if such grounded shields are separated by any distance from the detector planar electrode (which is typically biased to a high voltage, but in any case biased to a voltage different from that of the grounded shield) it becomes possible for the detector to vibrate relative to the shield. Through capacitive coupling, such vibration induces deleterious currents in the detector circuit, resulting in new noise. Such noise is known in the art as microphonic noise since the bias plane is microphonically coupled to the ground.

Therefore, there is a further need to devise an improved method of biasing the electrodes of gamma ray detectors while shielding those gamma ray detectors from electromagnetic interference in such a way that microphonic noise is eliminated. There is also a need to create lower cost shields for detector modules.

### SUMMARY OF THE INVENTION

The present subject matter relates to a cap or hood for a radiation detection device of the type that utilizes a semiconductor medium. The cap includes a bias connection pad on a first interior portion of the cap, and one or more steering electrodes on a second interior portion of the cap. The cap also includes a shielding layer.

In some aspects, the cap is shaped to receive a semiconductor medium, such that the bias connection pad will face a first face of the semiconductor medium, while a steering electrode will face a second face of the semiconductor medium.

In some aspects, the bias connection pad is electrically connected to a steering electrode. In other aspects, the bias connection pad is not electrically connected to any of the steering electrodes. In some aspects, the bias connection pad is equipotent with at least one of the steering electrodes. In some aspects, the bias connection pad is connected to a bias electrode of the semiconductor device and serves as a cathode or anode of a semiconductor detector.

In some aspects, the shielding layer is disposed on an exterior portion of the cap. In some aspects, an insulation layer is disposed between the bias connection pad and the shielding layer. In some aspects, an insulation layer is disposed between at least one of the steering electrodes and the shielding layer.

In some aspects, the cap includes one or more conductors which connect the semiconductor medium and cap to bias circuitry, detection circuitry, and/or processing circuitry.

In some aspects, the cap is formed of flexible circuit board, which may optionally be shaped in part like a free-sided box.

In some aspects, the bias electrode and the shielding layer are maintained with rigid fixed spacing to prevent independent vibration of the bias electrode with respect to the shielding layer. In some aspects, the bias connection pad and the shielding layer are maintained with rigid fixed spacing to prevent independent vibration of the bias connection pad with respect to the shielding layer.

In some aspects, the first interior portion of the cap and the second interior portion of the cap can be positioned on opposite parallel sides of a semiconductor medium.

In some aspects, a steering electrode is joined to the cap. In some aspects, a steering electrode is shaped to prevent electrons and holes in a semiconductor medium from becoming trapped at equipotent points within the semiconductor medium. In some aspects, a steering electrode is shaped like a grid.

In some aspects, a first portion of a steering electrode is electrically insulated from a second portion.

In some aspects, the cap includes a readout circuit card, which is optionally reinforced.

The present disclosure also includes a radiation detection device which includes a cap as above, and a semiconductor medium.

The present disclosure also includes a modular detector system in which a cap as above is attached to a mezzanine card. In some aspects, caps and mezzanine cards together form a detector array having a length×width×height configuration selected from the group consisting of: a 4×2×1 array, a 4×1×2 array, an 8×2×1 array, an 8×1×2 array, a 4×4×2 array, and a 4×4×3 array.

The present disclosure also includes a method of manufacturing a cap for a radiation detection device of the type that utilizes a semiconductor medium. The method includes the steps of disposing a bias connection pad on a first side of a flexible circuit board, disposing one or more steering electrodes on the first side of the flexible circuit board; disposing a shielding layer on a second side of the flexible circuit board; and shaping the flexible circuit board by manufacturing, folding, and/or cutting, such that the bias connection pad is positioned to face a first face of a semiconductor medium, while a steering electrode is positioned to face a second face of the semiconductor medium.

### BRIEF DESCRIPTION OF THE DRAWINGS

FIG. 1 illustrates a CZT detector assembly module having pixel cells (not visible), a planar bias electrode, and steering electrodes along the CZT detector edges.

FIG. 2 illustrates one embodiment of a cap according to the present subject matter, comprising a bias connection pad, one or more steering electrodes, and an outer shield.

FIG. 3 illustrates the construction of the cap of FIG. 2, and its relationship to a detector assembly.

FIG. 4 illustrates a further embodiment of a cap according to the present subject matter, comprising a bias connection pad, one or more steering electrodes, and an outer shield, integral with a flexible circuit board.

FIG. 5 illustrates a further embodiment of a cap according to the present subject matter, comprising a grid steering electrode.

FIG. 6 illustrates a further embodiment of a cap with a flexible circuit board according to the present subject matter, comprising a free-sided box shaped cap and a reinforced section for a readout circuit card.

FIG. 7 illustrates a mezzanine card according to the present subject matter.

FIG. 8 illustrates the mezzanine card of FIG. 7, with a plurality of the flexible circuit boards of FIG. 6 attached thereto.

FIG. 9 illustrates two mezzanine cards of FIG. 7, with a plurality of the flexible circuit boards of FIG. 6 attached thereto, forming a 4×1×2 array of detectors.

### DETAILED DESCRIPTION

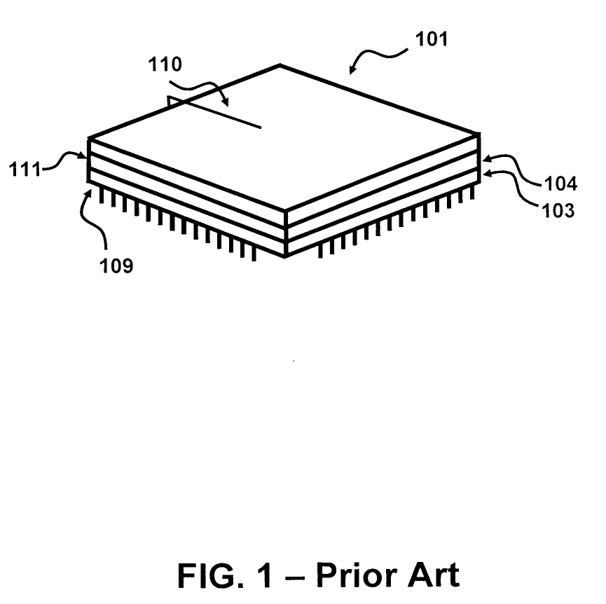

FIG. 1 shows a prior art CZT detector module 101 having an electronic readout substrate 103 and CZT detector 104 with planar bias electrode 109 and a steering electrode 111 which is metallized to wrap around the CZT detector 104. A bias voltage wire 110 is attached to the planar bias electrode 109 by means of a silver epoxy conductive adhesive bonding. This detector module would suffer from the deficiencies given above: the placement of a grounded shield around the detector would lead to microphonic coupling between such a shield and the bias electrode 109 which would not be fixed relative to each other. In addition, the attachment of the steering electrode 111 was costly, and was dangerous to the delicate semiconductor detector.

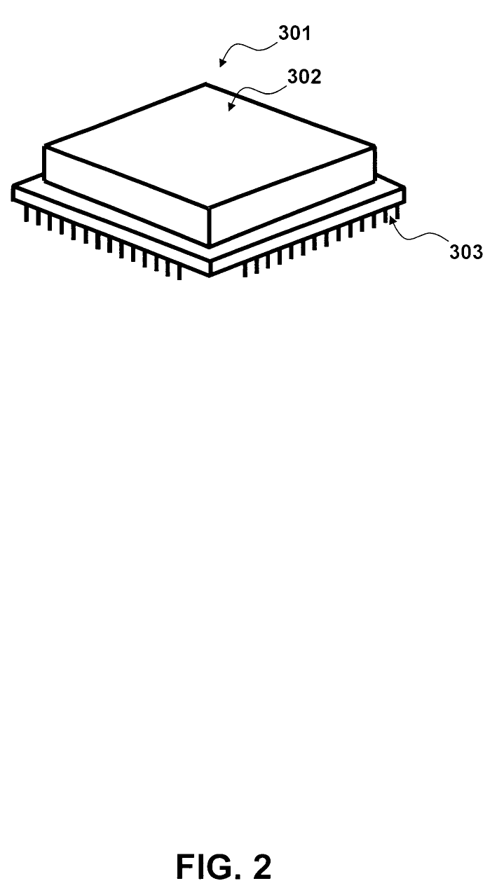

FIG. 2 shows a perspective view of a cap 302 according to the present subject matter. As depicted in FIG. 2, a detection module 301 is disposed on top of a readout circuit card 303, and includes a cap 302 which surrounds and shields the semiconductor detector beneath (not shown). Although a CZT or semiconductor detector is described herein, it will be clear to one of skill in the art that the present subject matter may be advantageously applied in similar fashion to many other types of radiation detectors, including detectors with crystals of other material, gamma ray detectors, alpha radiation detectors, beta radiation detectors, x-ray detectors, ionizing or ionized particle detectors, and neutron detectors.

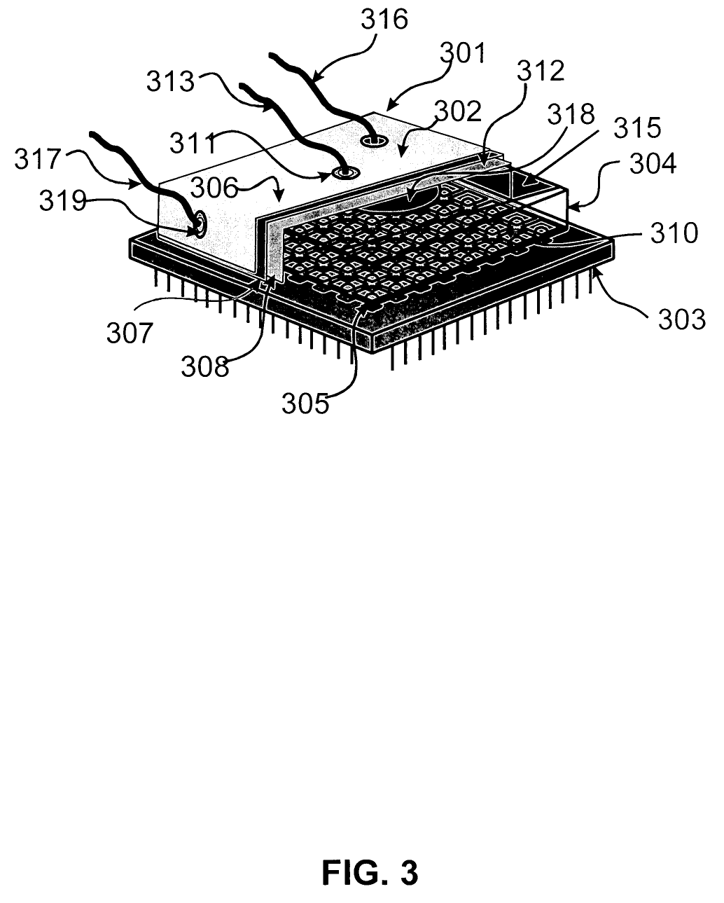

FIG. 3 shows the module 301 of FIG. 2, with the cap 302 partly cut away to reveal the features therein. The semiconductor medium 304 of the detection module 301 includes an array of pixel detection elements 310 at its bottom, which may be metallized thereon. Readout circuit card 303 is visible beneath the semiconductor medium 304. A plurality of connections 305 provide electrical connection for each detection element 310 to a corresponding input contact pad on the top surface of readout circuit card 303.

A bias planar electrode 315 of the detector is provided as part of the module 301 and is disposed on the top of the medium 304. The bias planar electrode 315 may serve as the cathode or anode for the semiconductor medium 304. This bias planar electrode may be metallized to the medium 304 or otherwise attached to the medium 304 of free therefrom. In the underside of the cap 302 is disposed a bias connection pad 312 which is provided as part of the cap 302. The bias connection pad 312 is bonded and electrically connected to the bias planar electrode 315 by an electrically conductive adhesive or a solder bond 318. The bias connection pad 312, which, in turn, connects to the bias planar electrode 315 by means of the conductive adhesive or solder bond 318, may be electrically connected to a bias voltage by means, such as a through via 311, to a bias voltage conductor 313. Other methods of providing bias voltage to the bias connection pad 312 may be used, such as providing the voltage by one or more connections at the underside of the cap 302. Also, although a planar bias electrode is shown, it should be clear that other types of bias electrodes may be used, including segmented bias electrodes.

One or more steering electrodes 308 can also be provided as part of the cap 302 and are disposed on the underside of the cap 302 along its edges surrounding the side surfaces of the medium 304, but may be electrically isolated from detector edges by means of an insulator which is attached to the medium 304 or the cap 302. The steering electrodes 308 serve to preferentially steer electrical charges within the semiconductor medium 304 away from the detector edges and into the detection elements 310. The steering electrodes 308 may be electrically connected to a bias voltage by means, such as a through via 319, to bias voltage conductors 317. Other methods of providing steering voltage to the steering electrodes 308 may be used, such as providing the voltage by one or more connections at the underside of the cap 302. The steering electrodes 308 may be physically and electrically integral with the bias connection pad 312, which reduces manufacturing costs and labor for the cap 302, and provides a steering bias at the same voltage as the bias electrode 315. However, steering electrodes 308 need not be integral with the bias connection pad 312, and the two may be held at different or variable potentials as needed. In addition, the steering electrodes 308 need not be integral all the way around the edge of the medium 304, particularly when different potentials are desired at different sides of the cap or at different levels of the medium 304. Additional vias, not shown, or other methods for electrical connection, may be used to provide separate potentials to the one or more steering electrodes.

The outer portion of the cap comprises an electrically conductive shield 306, which is electrically isolated from the bias connection pad 312 and steering electrodes 308 by insulation layer 307. The electrically conductive shield 306 may be kept at a fixed potential, or may be grounded, by means of a wire 316 attached by solder or by conductive bonding, or by means of any other electrical connection.

As the various electrodes and the shield 306 are both provided as part of the cap 302 and separated by insulation layer 307, they are held at a mechanically fixed distance from each other, thereby essentially eliminating microphonic coupling between the electrodes and shield 306 and thereby reducing noise.

The steering electrode 308 or electrodes are provided with the cap and can be insulated electrically from the medium 304, thereby creating no leakage currents and avoiding expensive and difficult electrode metallization at the medium 304. As the steering electrode 308 may be provided integrally with the bias connection pad 312, manufacturing costs and inconveniences may be further reduced.

In one embodiment of the present subject matter, the detection elements 310 comprise a plurality of cadmium-zinc-telluride (CZT) gamma-ray detection areas formed on the lower surface of medium 304. The detection elements 310 can alternatively comprise cadmium telluride, or other radiation sensitive materials such as x-ray, gamma-ray, and/or other radiation sensitive materials. The detection elements 310 convert x-rays, gamma rays, and/or other radiation into electrical charge pulses. The amplitude of the electrical pulses is indicative of the energy of the gamma rays absorbed. The bias electrode and steering electrodes steer the electrical charges formed within the detector substrate upon interaction with gamma photons or other radiation. As is known in the art, CZT crystals provide good energy and spatial resolution, can operate at room temperature, and can be manufactured in a variety of dimensions.

Devices of this type have many important potential uses in biological and clinical imaging applications, environmental remediation systems, nuclear radioisotope security systems, and space satellites. In medical/biological applications, these array detectors have applications in planar imaging, SPECT imaging systems, and as surgical probes. Some possible applications are mammography, clinical cardiology, in vivo auto radiography, neuroscience studies, and lymphatic system imaging. In nuclear medicine, arrays of CZT detectors can create superior images of injected radiotracers, thus aiding in removal of cancerous tissue while minimizing damage to healthy tissue. They can also be used for medical applications involving the exposure of a patient to ionizing radiation. Such applications require high radiation absorption characteristics for the detector substrate of the imaging device. Such high radiation absorption characteristics can be provided by materials using high Z element, such as found in CdZnTe (CZT) or CdTe. Furthermore, various medical applications require high spatial resolution. For example, mammography requires the ability to observe microcalcifications which can be under 100 microns or even under 50 microns in size. The stringent requirements imposed on imaging devices require the use of small resolution elements, or pixel cells, with a large array of such cells being needed to generate an image of a useful size.

Outside of biological and clinical uses, for environmental monitoring and remediation, as well as nuclear radioisotope security, gamma array detection can provide detailed information on radioisotopes present and their relative abundances. It also can be combined with an X-ray source to analyze the composition of non-radioactive isotopes through use of X-ray fluorescence, as for example, in examining the contents of a closed box or suitcase. In nuclear non-proliferation, the imaging of x-ray and gamma sources at a distance has the potential to detect illicit transport of radioactive materials. In astrophysics, CZT detector arrays are currently being employed in studies of distant gamma-burst sources.

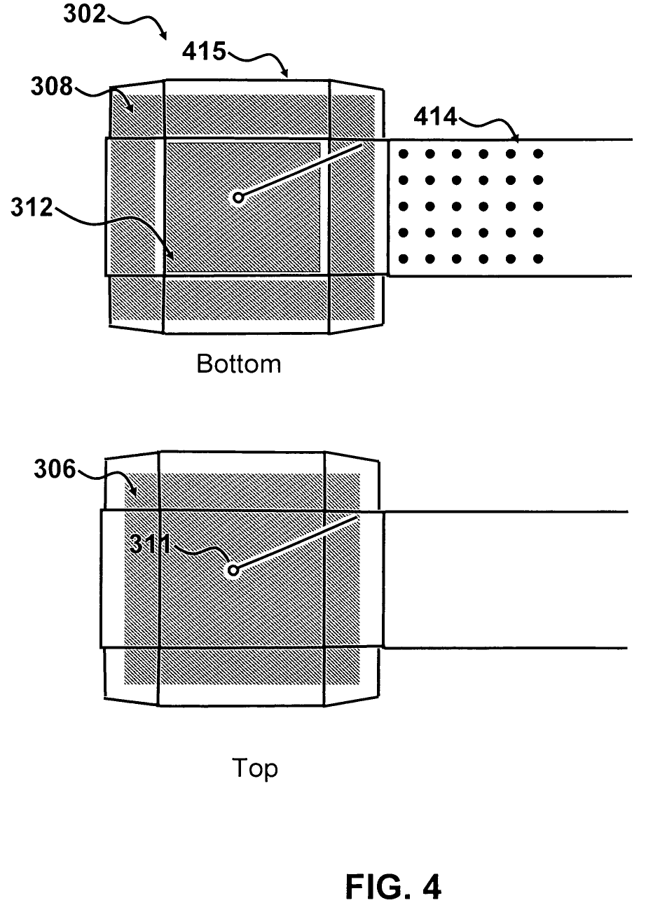

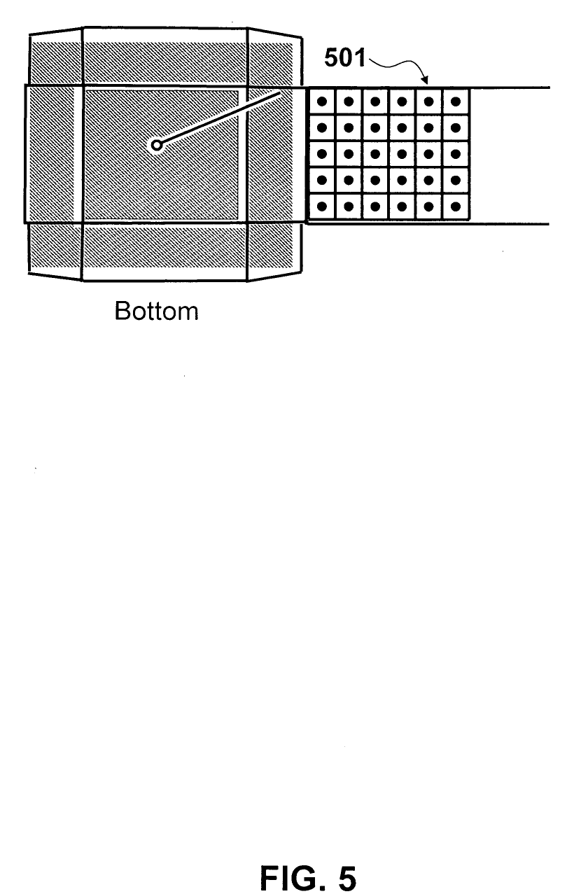

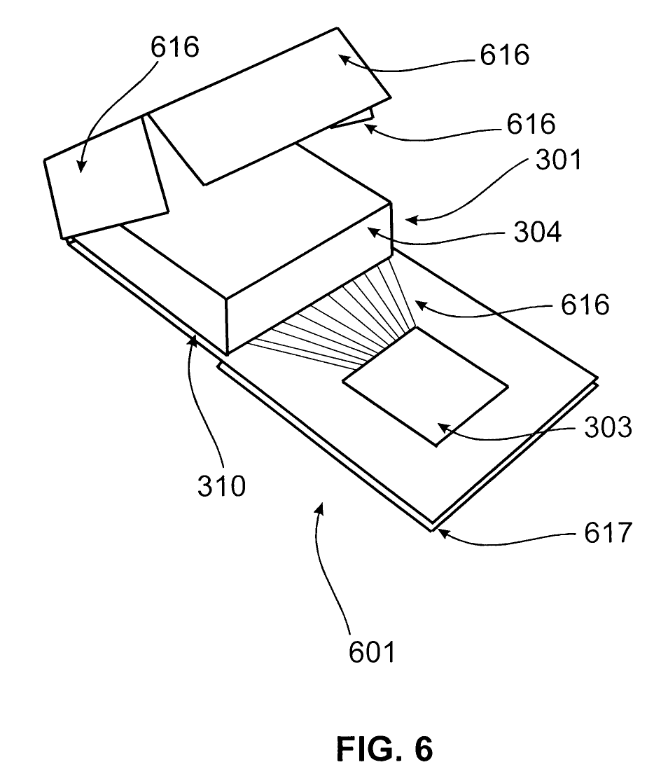

FIG. 4 shows another embodiment of a cap 302 according to the present subject matter, manufactured from a single flexible circuit board 415 which integrates the cap 302 and the readout circuit card (not shown, but visible in FIG. 6 below). This flexible circuit board may be a polyimide flex circuit, or any other sufficient flexible circuit board, and may be made rigid at particular regions, such as at a juncture of any readout circuit. Prior to placement on a detector, the cap 302 may be folded like a “cake box” into a three-dimensional structure. When folded, shielding 306 will surround the outside of the medium, while bias connection pad 312 will rest at the top of the medium, and may even be bonded to it. Steering electrodes 308 will then surround the detector. Steering electrodes 308 may be integral with the bias connection pad 312, or may be separate therefrom as shown. Further steering electrodes of a different type will be described below with reference to FIG. 5.

Bias connection pad 312 may be connected to a bias voltage source by way of a via 311, as discussed above, or alternatively, from a wire which is run perpendicular to the plane of a substrate beneath the bias electrode 315 and through the substrate. Such a substrate and associated pixel detection elements could be electrically connected to detection circuitry through the flexible circuit board 415 at connection pads 414, also integral with the circuit board. Alternatively, detection elements could be disposed directly on the flexible circuit board 415 in lieu of a connection panel 414, and electrically connected through the flexible circuit board 415 to detection circuitry. Pixel detection elements are not the only detection elements which may be used; others include strip detection elements or detection elements of any other shape.

FIG. 5 illustrates a cap on which a grid steering electrode 501 has been disposed. Unlike the steering electrodes described above, which may be disposed at the sides of the detector semiconductor or at the top of the detector semiconductor (near to, adjacent to, or even integral with the bias electrode), grid steering electrode 501 is disposed at the underside of the detector semiconductor, where the semiconductor detector is joined to the flexible circuit board. Electrons and holes generated in the detector semiconductor normally travel a path of least resistance to the cathode or anode, arriving at a particular pixel surface. However, electrons or holes generated near a region which is equipotent for two pixel surfaces may become trapped near that equipotent point until thermal changes or other random processes release the electron or hole, thereby reducing the sensitivity of the detector. The grid steering electrode 501, which may be held or modulated at any desired voltage or voltages, is aligned directly between the pixel surfaces of the detector, and prevents electrons or holes from becoming trapped at in areas equidistant to two pixels. The grid steering electrode may be metallized to the detector, but is preferably layered on or in the circuit board of the cap, or rests over the circuit board of the cap, and comes in contact with (or proximity to) the semiconductor detector only when the detector is placed at the circuit board of the cap. The steering electrode may also be in the form of one or a concentric plurality of squares, rectangles, or other shape desirable. The choice of shape for steering electrode will influence the size and shape of the resulting “voxels,” or volume spaces of crystal whose electrons or holes are directed to a particular surface pixel, but should in any case prevent the trapping of electrons or holes. Portions of the steering electrode may be electrically insulated from each other and held at different potentials. For example, a medial (central) portion of the steering electrode may be held at a first potential, and a lateral (outer) portion of the steering electrode may be held at a second potential. If desired, each “square” surrounding a pixel may be held at a different voltage. Such flexibility allows the steering electrode to be tuned, to more effectively avoid trapping in the semiconductor.

FIG. 6 illustrates a further embodiment of a cap with a flexible circuit board, together labeled 601. Here, detection module 301 comprises a semiconductor medium 304, and (as discussed above) is covered by a free-sided box shaped cap formed from the flexible circuit board (note that the shape resembles a typical “cake box”). The flexible circuit board is cut as to form side pieces 616 which fold over each side of the semiconductor medium 304, and which may be then fixedly attached to the flexible circuit board. Thus, the circuit board is shaped to cover all sides of the semiconductor detector. Side pieces 616 may comprise the steering electrode 308 described above, on their interior sides. This is only one configuration by which all sides of the semiconductor detector may be covered, and others may be used with the present disclosure.

The detection module 301 rests on connection pads 414 (not visible), which in turn connect to circuit traces 616, which lead to readout circuit card 303, to which a readout chip may be attached. The placement of a readout chip in position 303 minimizes the impedance of the traces between the readout chip and the semiconductor detector. The minimization of this impedance is paramount to the minimization of the leakage current onto the readout preamplifiers and subsequent maximization of energy resolution. Between connection pads 414 a grid steering electrode (not visible) may be disposed. This grid steering may be composed of a single or multiple electrical conductors so that one or multiple voltages (and electrical fields) can be applied under the semiconductor detector. The underside of readout circuit card 303 may have a ball grid array predisposed thereon, for easy of connection of the readout circuit card 303 to further output circuitry. The section for a readout circuit card may be reinforced with a rigid reinforcement surface 617. This reinforcement (or “rigidization”) can assist in attachment of the readout electronics, and/or in attachment of the circuit board to another surface. The cap-circuit units 601 are shaped to facilitate assembly of a plurality of semiconductors, each attached to a separate such cap and circuit board, in a modular fashion.

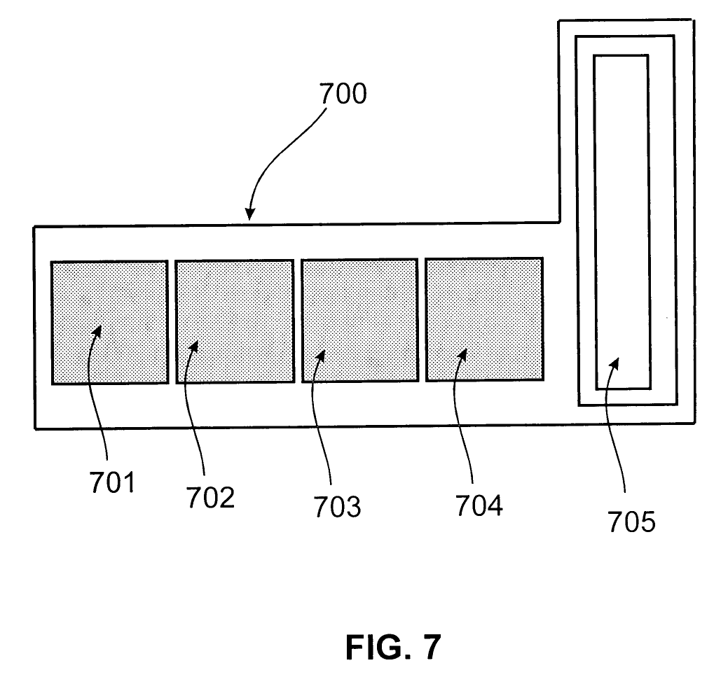

FIG. 7 illustrates a mezzanine card 700, to which a plurality of cap-circuit units may be attached for such a modular arrangement. The mezzanine card 700 comprises a plurality of attachment zones 701, 702, 703, and 704 to which the cap-circuit units attach. Although four attachment zones are shown, this is a non-limiting example, and other numbers of cap-circuit units may be attached thereto. The mezzanine card 700 comprises traces or wires for placing the attachment zones 701, 702, 703, and 704 in electric communication with attachment port 705.

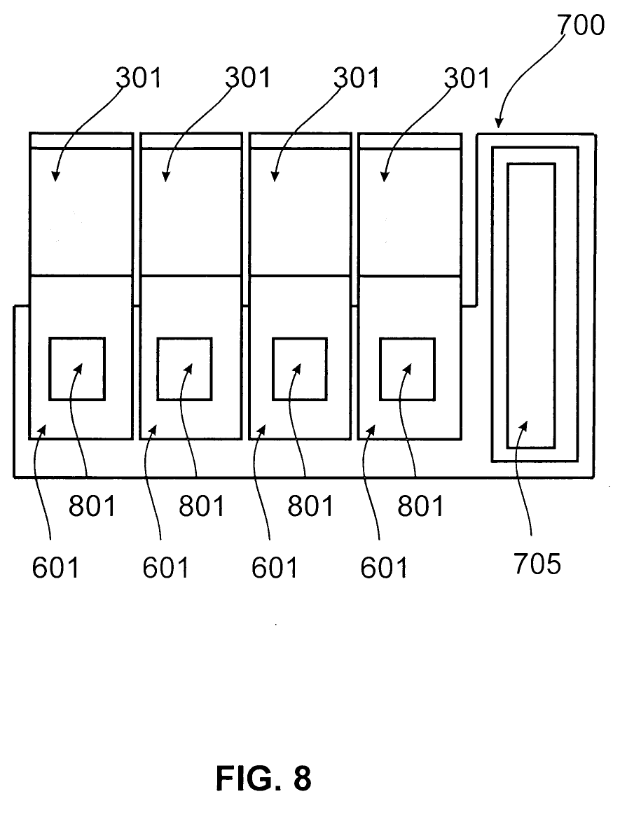

FIG. 8 illustrates the mezzanine card 700 with four cap-circuit units 601 attached. Each cap-circuit unit 601 includes a detection module 301 and a readout chip 801, and the readout chip 801 is in electronic communication with the traces or wires of the mezzanine card (not visible), and thus each readout chip 801 is in electric communication with attachment port 705. In this way, a computer or motherboard may read all four detection modules from a corresponding port connected to the attachment port. Thus, a 4×1×1 array of detector modules is formed.

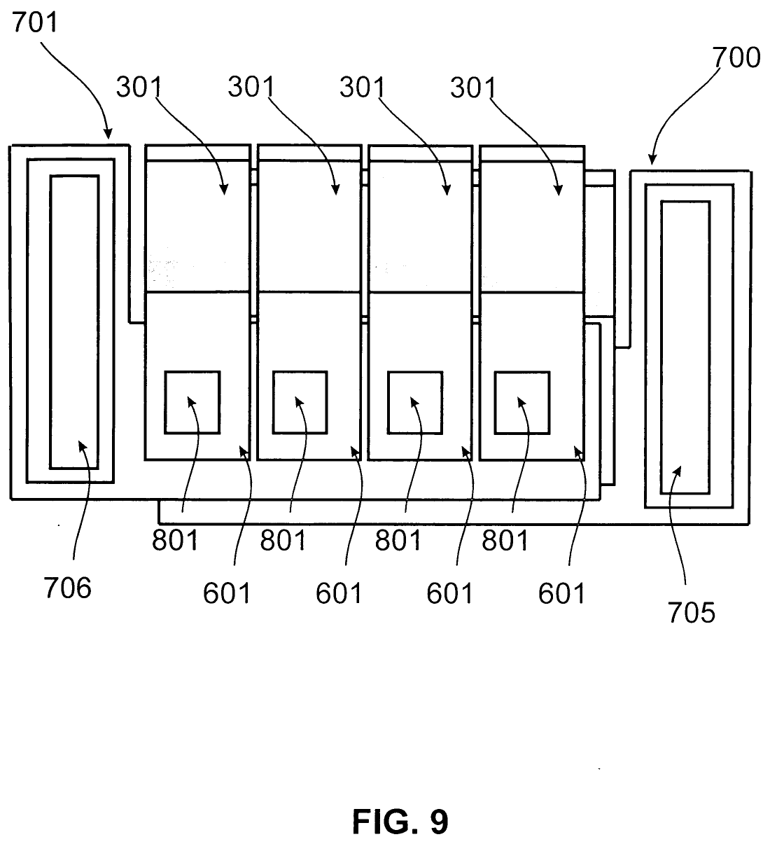

FIG. 9 illustrates two mezzanine cards 700 and 701, each with four cap-circuit units 601 attached. Again each cap-circuit unit 601 includes a detection module 301 and a readout chip 801, and the readout chip 801 is in electronic communication with the traces or wires of the mezzanine card. Together, the two mezzanine cards form a 4×1×2 array of detectors. Here, the “top” four cap-circuit units 601 are thus in communication with attachment port 706, while the “bottom” four cap-circuit units 601 are thus in communication with attachment port 705. Similarly, any number of detectors may be assembled using any number of mezzanine cards 700 and 701, and any number of cap-circuit units 601 with detection modules 301, in all three dimensions. As non-limiting examples, the semiconductor detectors may be assembled in one or more of the following length×width×height arrays: a 4×2×1 array, a 4×1×2 array, an 8×2×1 array, an 8×1×2 array, a 4×4×2 array, or a 4×4×3 array. Optionally, the two mezzanine cards may connect to a single motherboard.

A cap for an x-ray or gamma ray detection device having a semiconductor detector, such as those described above, may be manufactured according to the following method. A flexible circuit board may be provided with a shape such as that illustrated in FIG. 4, or another advantageous shape. The circuit board need not be immediately provided with the shape, however, and may be cut to an appropriate shape during or after manufacture. First, a bias electrode is disposed on a first side of the flexible circuit board, by any known circuit fabrication method. Then, at least one steering electrode is disposed on the first side of the flexible circuit board, by any known circuit fabrication method. If the steering electrode and bias connection pad are to be contiguous and equipotent, the steering electrode(s) and bias connection pad may be applied simultaneously. Separately, a shielding layer is disposed on a second side of the flexible circuit board, by any known circuit fabrication method. If one or more vias are to be disposed for access to the electrodes and/or shielding, these may be disposed on the appropriate sides at this time. Additional electrical connections to, from, or between the above elements may also be disposed at this time. The detector is then bonded to the flexible circuit at the bonding pads 414, optionally over a grid electrode. Then, the flexible circuit board is folded over the detector so that the steering electrode(s) are placed in a fixed geometric arrangement with the bias electrode. If the steering electrode is an edge electrode, it may be positioned substantially perpendicular to the bias electrode. If the steering electrode is a grid electrode or the like, it may be positioned substantially parallel to the bias electrode, such that the steering electrode is on a face of a semiconductor medium opposite the face on which the bias electrode sits. The bias connection pad may then be bonded to the detector top surface by conductive adhesive or solder. This is only one method for manufacture of the present subject matter, and others are possible and will be clear to those skilled in the art.

The previous description of some aspects is provided to enable any person skilled in the art to make or use the present subject matter. Various modifications to these aspects will be readily apparent to those skilled in the art, and the generic principles defined herein may be applied to other aspects without departing from the spirit or scope of the subject matter. For example, one or more elements can be rearranged and/or combined, or additional elements may be added. Thus, the present subject matter is not intended to be limited to the aspects shown herein but is to be accorded the widest scope consistent with the principles and novel features disclosed herein.

What is claimed is:

1) A cap for a radiation detection device of the type that utilizes a semiconductor medium, the cap comprising:
a bias connection pad disposed on a first interior portion of the cap;
one or more steering electrodes disposed on a second interior portion of the cap; and
a shielding layer disposed at the cap.

2) A cap according to claim 1, wherein
the cap is shaped to receive a semiconductor medium;
the bias connection pad is positioned to face a first face of the semiconductor medium; and
at least one of the steering electrodes is positioned to face a second face of the semiconductor medium.

3) A cap according to claim 1, wherein the bias connection pad is electrically connected to at least one of the steering electrodes.

4) A cap according to claim 1, wherein the bias connection pad is not electrically connected to any of the steering electrodes.

5) A cap according to claim 1, wherein the bias connection pad is equipotent with at least one of the steering electrodes.

6) A cap according to claim 1, wherein the bias connection pad is connected to a bias electrode of the semiconductor device and serves as a cathode or anode of a semiconductor detector.

7) A cap according to claim 1, wherein the shielding layer is disposed on an exterior portion of the cap.

8) A cap according to claim 1, further comprising an insulation layer disposed between the bias connection pad and the shielding layer.

9) A cap according to claim 1, further comprising an insulation layer disposed between at least one of the steering electrodes and the shielding layer.

10) A cap according to claim 1, further comprising one or more conductors which connect the semiconductor medium and cap to circuitry selected from the group consisting of: bias circuitry, detection circuitry, processing circuitry, or combinations thereof.

11) A cap according to claim 1, wherein the cap is formed of flexible circuit board.

12) A cap according to claim 11, wherein the flexible circuit board is shaped in part like a free-sided box.

13) A cap according to claim 1, wherein the bias electrode and the shielding layer are maintained with rigid fixed spacing to prevent independent vibration of the bias electrode with respect to the shielding layer.

14) A cap according to claim 1, wherein the bias connection pad and the shielding layer are maintained with rigid fixed spacing to prevent independent vibration of the bias connection pad with respect to the shielding layer.

15) A cap according to client 1,
wherein the first interior portion of the cap and the second interior portion of the cap can be positioned on opposite parallel sides of a semiconductor medium.

16) A cap according to claim 15, wherein at least one of the steering electrodes is joined to the cap.

17) A cap according to claim 15, wherein at least one of the steering electrodes is shaped to prevent electrons and holes in a semiconductor medium from becoming trapped at equipotent points within the semiconductor medium.

18) A cap according to claim 17, wherein at least one of the steering electrodes is shaped like a grid.

19) A cap according to claim 17, wherein at least one of the steering electrodes comprises a first portion electrically insulated from a second portion.

20) A cap according to claim 1, the cap further comprising a readout circuit card.

21) A cap according to claim 20, wherein the readout circuit card is reinforced.

22) An radiation detection device comprising:
a cap according to claim 1; and
a semiconductor medium.

23) A modular detector system comprising:
at least one cap according to claim 1; and
at least one mezzanine card to which the at least one cap is attached.

24) The modular detector system of claim 23, wherein the at least one cap and the at least one mezzanine card together form a detector array having a length×width×height configuration selected from the group consisting of: a 4×2×1 array, a 4×1×2 array, an 8×2×1 array, an 8×1×2 array, a 4×4×2 array, and a 4×4×3 array.

25) A method of manufacturing a cap for a radiation detection device of the type that utilizes a semiconductor medium, the method comprising:
disposing a bias connection pad on a first side of a flexible circuit board;
disposing one or more steering electrodes on the first side of the flexible circuit board;
disposing a shielding layer on a second side of the flexible circuit board; and
shaping the flexible circuit board by manufacturing, folding, cutting, or combinations thereof, such that the bias connection pad is positioned to face a first face of a semiconductor medium, while the at least one of the steering electrodes is positioned to face a second face of the semiconductor medium.
